(19) United States
(12) Patent Application Publication
(10) Pub. No.: US 2011/0188663 A1
(43) Pub. Date: Aug. 4, 2011

(54) ARTIFICIAL ENGINE SOUND GENERATOR

(75) Inventor: Toshiaki NAKAYAMA, Miyoshi-city (JP)

(73) Assignee: DENSO CORPORATION, Kariya-city (JP)

(21) Appl. No.: 13/019,545

(22) Filed: Feb. 2, 2011

(30) Foreign Application Priority Data
Feb. 2, 2010 (JP) 2010-21188

(51) Int. Cl. H03G 3/20; H03G 5/00

(52) U.S. Cl. 381/57; 381/98; 381/86

(57) ABSTRACT

An artificial engine sound generator for producing an artificial engine sound includes: a main body device that defines a predetermined frequency selected in a range between 1 Hz and 10 Hz, and simultaneously generates a plurality of signals having frequencies, which are arranged at intervals of the predetermined frequency, so that the artificial engine sound is formed. In the generator, data for producing the artificial engine sound is minimized, and therefore, a calculation load for producing the artificial engine sound is reduced.

### CROSS REFERENCE TO RELATED APPLICATION

This application is based on Japanese Patent Application No. 2010-21188 filed on Feb. 2, 2010, the disclosure of which is incorporated herein by reference.

### FIELD OF THE INVENTION

The present invention relates to an artificial engine sound generator for generating an artificial engine sound so as to notify existence of a vehicle.

### BACKGROUND OF THE INVENTION

A vehicle such as an electric vehicle, a fuel cell vehicle and a hybrid vehicle runs with using an electric motor, which generates a rotation force when the motor is energized. The vehicle generates and outputs sound to the outside of the vehicle, and the sound is smaller than that of a conventional vehicle having a power source of an engine (i.e., a combustion engine). Accordingly, a person may not recognize existence of the vehicle.

Thus, a vehicle existence notification apparatus is proposed. The notification apparatus generates and outputs notification sound so that the apparatus notifies existence of the vehicle.

The vehicle existence notification apparatus outputs, for example, an artificial engine sound as the notification sound for notifying the existence of the vehicle.

However, it is difficult to generate the artificial engine sound.

Specifically, a conventional technique for generating the artificial engine sound is such that an actual engine sound is recorded and stored, and the recorded engine sound is reproduced according to a driving condition of the vehicle. This technique is disclosed in JP-A-2005-115166.

Specifically, the actual engine sound generated from a single cylinder of the engine is recorded with various engine rotations according to various opening degrees of an acceleration pedal. Then, the engine sound is recorded as a waveform data having a unit of one cycle of combustion (i.e., one burning cycle). Thus, the waveforms in one unit are memorized in accordance with the opening degree of the acceleration pedal.

When the vehicle runs, the waveform in one unit is retrieved from a memory according to the opening degree of the acceleration pedal, which is operated by a driver. Then, the waveforms are continuously retrieved so that continuous waveform data is generated. Multiple continuous waveform data are overlapped in accordance with the number of cylinders in the engine so that the artificial engine sound is synthesized.

However, when the actual engine sound is recorded in various opening degrees of the acceleration pedal, the waveform of the recorded engine sound is divided into the waveform in one unit, and the divided waveform of the one unit is stored in association with the opening degree of the acceleration pedal, a huge number of labor hours and a huge number of memory data are necessary.

Further, when multiple waveform data of the one unit are continuously coupled with each other, and the artificial engine sound is synthesized by overlapping the multiple waveform data, calculation amount of data is huge. Thus, calculation load for generating the artificial engine sound is much large.

### SUMMARY OF THE INVENTION

In view of the above-described problem, it is an object of the present disclosure to provide an artificial engine sound generator for generating an artificial engine sound so as to notify existence of a vehicle. Calculation load for generating the artificial engine sound is comparatively small, and data for generating the artificial engine sound is simplified.

According to an aspect of the present disclosure, an artificial engine sound generator for producing an artificial engine sound includes: a main body device that defines a predetermined frequency selected in a range between 1 Hz and 10 Hz, and simultaneously generates a plurality of signals having frequencies, which are arranged at intervals of the predetermined frequency, so that the artificial engine sound is formed.

In the above generator, since the main body device simultaneously generates a plurality of signals having frequencies, which are arranged at intervals of the predetermined frequency, data for producing the artificial engine sound is minimized, and a calculation load for producing the artificial engine sound is reduced.

### BRIEF DESCRIPTION OF THE DRAWINGS

The above and other objects, features and advantages of the present invention will become more apparent from the following detailed description made with reference to the accompanying drawings. In the drawings:

FIG. 1 is a diagram showing an artificial engine sound generator;

FIG. 2A is a diagram showing a font view of an ultrasonic sound wave speaker, and FIG. 2B is a diagram showing a top view of the speaker;

FIGS. 3A to 3C are graphs showing constitution of an artificial engine sound;

FIGS. 4A to 4E are graphs showing an operation method of a parametric speaker according to a first embodiment;

FIG. 5 is a graph showing a relationship between a frequency of an environmental noise and a sound pressure level at a specific high frequency in the artificial engine sound;

FIGS. 6A and 6B are graphs showing constitution of an artificial engine sound according to a second embodiment; and

FIGS. 7A and 7D are graphs showing constitution of an artificial engine sound according to a third embodiment.

### DETAILED DESCRIPTION OF THE PREFERRED EMBODIMENTS

An artificial engine sound generator defines a selected frequency as “AHz,” which is selected between 1 Hz and 10 Hz, and generates multiple frequency signals at the same time so that the artificial engine sound generator generates an artificial engine sound. The multiple frequency signals are arranged at intervals of the selected frequency “AHz.”

Preferably, the artificial engine sound may include high frequency signals, which are in a range between 3 kHz and 7 kHz, and low and middle frequency signals, which are, for example, a 2 kHz signal, a 1 kHz signal and 500 Hz signal. The high frequency signals are, for example, 4 kHz signals, sounds of which are dissonance and abrasive for a person so that the sounds easily stick in his or her ear. The sounds of the low and middle frequency signals are harmonious for a person, and, for example, constitute multiple frequency signals having overtone relationship.

The artificial engine sound may be generated by a parametric speaker so that the artificial engine sound includes audible sounds, which are audible at a point distant from a vehicle. Alternatively, the artificial engine sound may be generated by a speaker for directly generating audible sounds so that the audible sounds are output from the vehicle.

The selected frequency “AHz” may be fixed to a predetermined frequency such as 4 Hz. Alternatively, the selected frequency “AHz” may be varied in a predetermined range such as a range between 1 Hz and 10 Hz according to an opening degree of an acceleration pedal, which is operated by a passenger of the vehicle. Alternatively, the selected frequency “AHz” may fluctuate in a predetermined range such as a range between 3.5 Hz and 4.5 Hz.

A sound pressure level of the artificial engine sound may be fixed to a predetermined sound pressure level. Alternatively, the sound pressure level may be automatically controlled according to a sound pressure level of environmental noise. Alternatively, the sound pressure level may be continuously or step-wisely increased as the opening degree of the acceleration pedal is made large.

### First Embodiment

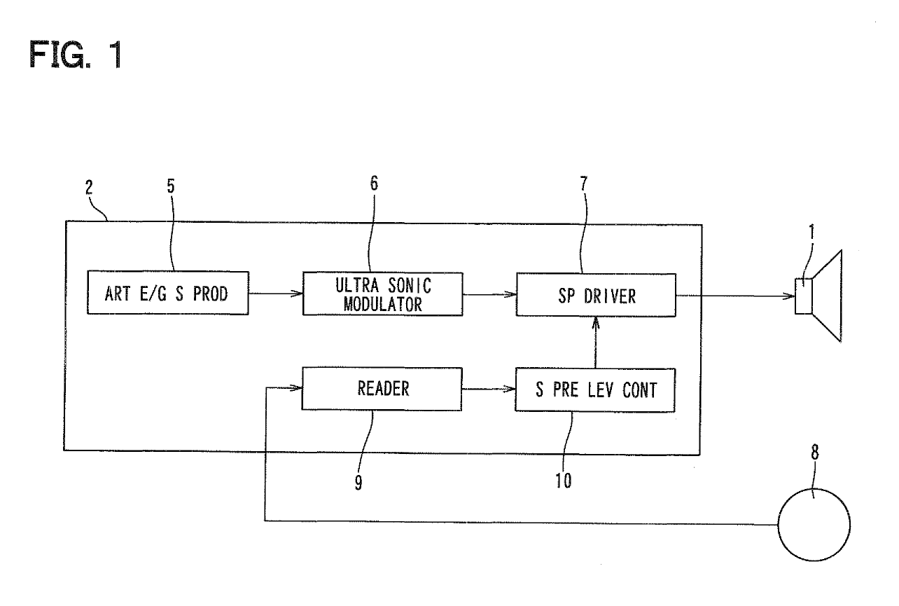

The artificial engine sound generator is suitably used for a vehicle existence notification apparatus. The artificial engine sound is shown in FIGS. 1 to 5.

In the present embodiment, the artificial engine sound is generated by a parametric speaker so that the artificial engine sound includes audible sounds, which are audible at a point distant from the vehicle.

As shown in FIG. 1, the vehicle existence notification apparatus includes an ultra sonic speaker 1 for outputting an ultra sonic wave and a main body device 2 for controlling the ultra sonic speaker 1.

The ultra sonic speaker 1 is mounted on a front side of the vehicle so that the speaker 1 generates and emits the ultra sonic wave to the outside of the vehicle.

A mounting place of the speaker 1 is as follows.

When the vehicle such as a hybrid vehicle includes a combustion engine for generating a rotation force with using fuel burning phenomenon, the ultra sonic speaker 1 is mounted on an inner wall of an opening of a radiator grill for introducing outside air so that the ultra sonic wave generated by the speaker 1 is emitted to the outside of the vehicle to a forward direction. For example, the ultra sonic wave is obliquely output to the forward direction on a sidewalk. The opening of the radiator grill is an air inlet for wind when the vehicle runs so that the wind cools a radiator of the vehicle. Thus, the opening of the radiator grill faces the front side of the vehicle. Here, even when the vehicle is an electric vehicle so that the electric vehicle does not include a radiator, the speaker 1 may be mounted on an inner wall of an air inlet for wind.

In the present embodiment, the speaker 1 is mounted on the front side of the vehicle. Alternatively, the speaker 1 may be mounted on a rear side or a bottom of the vehicle so that the speaker 1 outputs the artificial engine sound to a rear direction of the vehicle when a driver reverses the vehicle.

The irradiation direction of the ultra sonic wave output from the speaker 1 may be fixed to a certain direction. Alternatively, the irradiation direction of the ultra sonic wave may be controllable according to a driving condition, The control element for controlling the irradiation direction of the ultra sonic wave may be such that multiple speakers 1 having different irradiation directions are mounted on the vehicle, and the control element switches the speakers 1. Alternatively, the control element for controlling the irradiation direction of the ultra sonic wave may be such that the control element controls an electric actuator such as a solenoid for displacing a support member of the speaker 1.

A construction of the speaker 1 will be explained.

The speaker 1 is an ultra sonic wave generator for generating air vibration having a frequency equal to or higher than audible band of a person, i.e., higher than 20 kHz. The ultra sonic wave has strong directivity. Thus, the ultra sonic wave strongly goes straight in the air. Accordingly, the speaker 1 can irradiate the ultra sonic wave to a specific direction with respect to the vehicle. The specific direction is a required direction to which the ultra sonic wave is irradiated. For example, the specific direction is a forward and slant direction of the vehicle so that the speaker 1 irradiates the ultra sonic wave toward the sidewalk.

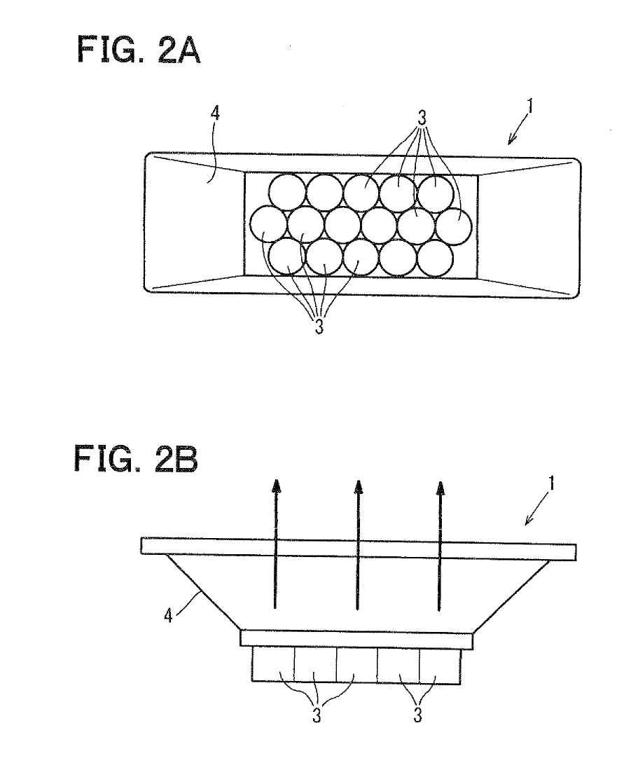

FIGS. 2A and 2b show the speaker 1. The speaker 1 includes multiple Piezo-electric speakers 3, which are suitably used for generating the ultra sonic wave. The Piezo-electric speaker 3 is a ceramic speaker or a Piezo speaker. Thus, the speaker 1 provides a speaker array.

In the present embodiment, the Piezo-electric speaker 3 includes a Piezo element and a vibration plate. The Piezo element is expandable according to a voltage applied to the element so that the Piezo element is charged and discharged. The vibration plate conducts vibration to the air when the Piezo element expands and contracts.

The energy of the ultra sonic wave generated by the speaker 1 and the directivity range of the ultra sonic wave output from the speakers 3 are controlled by the number and arrangement of the speakers 3. Further, the directivity range of the ultra sonic wave output from the speakers 3 may be controlled by a horn 4.

In the present embodiment, the ultra sonic speaker 1 includes the Piezo-electric speakers 3. Alternatively, the ultra sonic speaker 1 may include other types of speaker as long as the speaker can generate the ultra sonic wave.

The main body device 2 for operating the speaker 1 will be explained.

The main body device 2 includes an artificial engine sound producing element 5, an ultra sonic wave vibration modulator 6, and a speaker driver 7. The artificial engine sound producing element 5 produces a frequency signal for providing the artificial engine sound. The ultra sonic wave vibration modulator 6 modulates the frequency signal for providing the artificial engine sound to the ultra sonic frequency signal. The speaker driver 7 drives the speaker 1 with using the modulated ultra sonic frequency signal. The main body device 2 is controlled by an operation signal from a ECU (i.e., engine control unit). Here, the operation signal is an instruction signal for instructing generation of the artificial engine sound.

The main body device 2 further includes an automatic adjusting element and a power source (not shown). The automatic adjusting element automatically adjusts an output level of the speaker 1 based on the environmental noise of the vehicle. The output level is a sound volume. The power source is coupled with an in-vehicle power source such as a battery of the vehicle so that the power source supplies electricity to each circuit of the main body device 2. Thus, each circuit of the main body device 2 as an electric function element functions.

Each circuit of the main body device 2 will be explained.

The artificial engine sound producing element 5 includes a conventional computer having a CPU for executing various processes, a memory for storing various programs, an input circuit, an output circuit and the like. The memory stores an artificial engine sound generation program as an audio soft ware for generating the frequency signal for providing the artificial engine sound with using a digital technique.

The artificial engine sound generation program provides to generate the frequency signal, i.e., a waveform signal, for providing the artificial engine sound based on a clock signal. A reference clock in the computer generates the clock signal. The reference clock is a crystal oscillator. Specifically, the artificial engine sound generation program provides to define a selected frequency as “AHz,” which is selected between 1 Hz and 10 Hz, and to generate multiple frequency signals at the same time so that the artificial engine sound is generated. The multiple frequency signals are arranged at intervals of the selected frequency “AHz.”

In this embodiment, the selected frequency “AHz” is 4 Hz, which is fixed. Alternatively, the selected frequency “AHz” may be a fixed frequency selected between 3.5 Hz and 4.5 Hz.

In the present embodiment, the frequency signals for providing the artificial engine sound are provided by multiple frequency signals, which are arranged at intervals of 4 Hz. Alternatively, the frequency signals for providing the artificial engine sound may be provided by deleting a part of the multiple frequency signals. Specifically, the multiple frequency signals arranged at intervals of the selected frequency “AHz” partially lacks.

The artificial engine sound generation program includes a frequency range specifying program for generating a part of multiple frequency signals arranged at intervals of 4 Hz, which are disposed in a predetermined frequency range.

Here, the predetermined frequency range will be explained.

In the present embodiment, the predetermined frequency range is determined based on the frequency property of the actual engine sound, which is generated by the engine of the vehicle. In a second embodiment, the predetermined frequency range is determined to provide the artificial engine sound to be an equitempered scale.

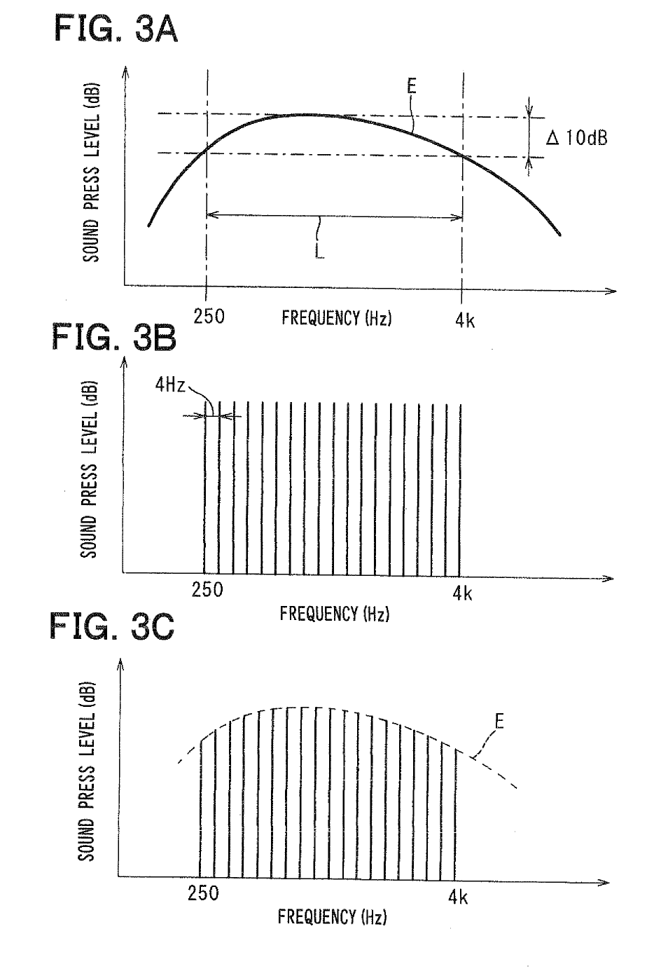

When the frequency property of the actual engine sound is a property defined as a solid line E in FIG. 3A, the frequency range of the actual engine sound, which is audible for a person, is a main frequency range L. The main frequency range L is defined by a frequency range of the sound pressure within maximum pressure minus ten decibels. Specifically, the main frequency range L is defined by the sound pressure between the maximum sound pressure and a sound pressure prepared by subtracting ten decibels from the maximum sound pressure. The sound having the sound pressure level out of the main frequency range L is not substantially recognized by a person because the sound is masked by the sound in the main frequency range L. Thus, the sound having the low sound pressure level is not detected by the person.

The artificial engine sound generation program provides to produce multiple frequency signals, which are arranged at intervals of 4 Hz, only in the main frequency range L, as shown in FIG. 3B since a person can hear the sound only in the main frequency range L. The multiple frequency signals only in the main frequency range L provide the artificial engine sound.

The above process will be explained in detail.

When the artificial engine sound similar to the actual engine sound of a specific type of a vehicle is produced, firstly, the actual engine sound of the specific type of the vehicle is measured.

The frequency range of the sound pressure between the maximum sound pressure and the sound pressure prepared by subtracting ten decibels from the maximum sound pressure is measured in the actual engine sound.

The measured frequency range provides the main frequency range L. When the main frequency range is, for example, in a range between 250 Hz and 4 kHz, the artificial engine sound generation program provides to generate the frequency signals for providing the artificial engine sound in a range between 250 Hz and 4 kHz, as shown in FIG. 3B.

The artificial engine sound generation program further includes a frequency property processing program for processing the frequency property of multiple frequency signals arranged at intervals of 4 Hz. The processing of the frequency property is to characterize the frequency property.

An example of the processing of the frequency property will be explained as follows.

When the artificial engine sound similar to the actual engine sound of a specific type of a vehicle is produced, the frequency property of the actual engine sound of the specific type of the vehicle is measured and shown as the solid line E in FIG. 3A.

In this case, the frequency property of the frequency signals for providing the artificial engine sound is process to be fit with the frequency property of the actual engine sound of the specific type of the vehicle so that the frequency signals for providing the artificial engine sound has the frequency property shown as a dotted line E in FIG. 3C. Specifically, the maximum sound pressure of each frequency signal is disposed on the maximum sound pressure of the actual engine sound of the specific type of the vehicle. Here, the frequency property of the frequency signals is defined by an outline of the maximum sound pressure of the frequency signals.

The ultra sonic wave vibration modulator 6 includes an ultra sonic wave generator for generating the ultra sonic wave having an ultrasonic wave frequency such as 25 kHz, which is higher than 20 kHz. The ultra sonic wave vibration modulator 6 modulates a voltage change of a waveform signal output from the artificial engine sound producing element 5 to be an amplitude change of an oscillation voltage of the ultra sonic wave frequency. Here, the waveform signal is the frequency signal for producing the artificial engine sound.

In the present embodiment, the main body device 2 includes the ultra sonic wave vibration modulator 6 independently. Alternatively, the above artificial engine sound generation program may include a program for providing function of the ultra sonic wave vibration modulator 6.

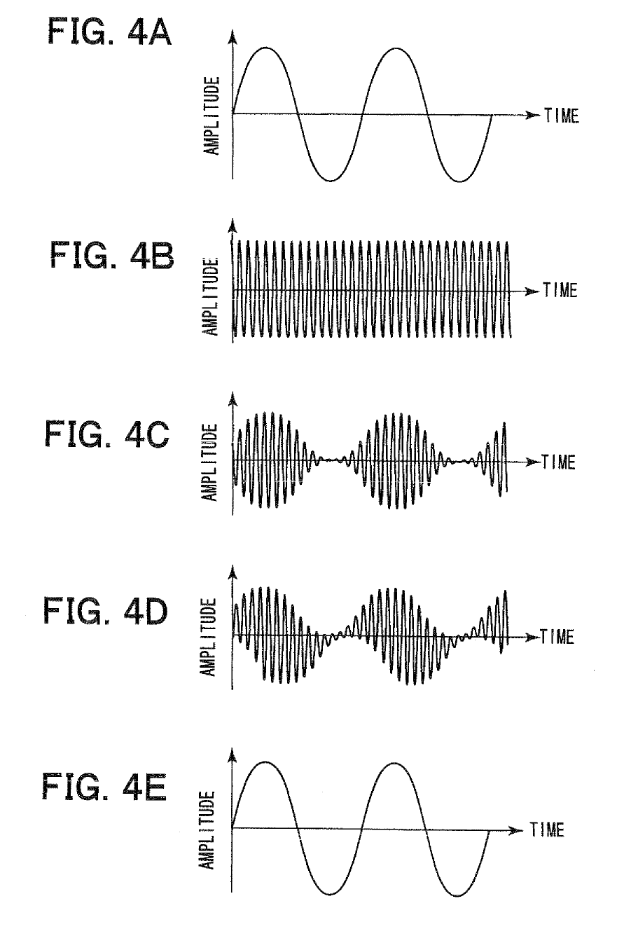

The ultra sonic wave modulation process executed by the ultra sonic wave vibration modulator 6 will be explained with reference to FIGS. 4A to 4E. Here, in the ultra sonic wave modulation process, the frequency signals for providing the artificial engine sound is modulated to the amplitude change of the oscillation voltage of the ultra sonic wave.

For example, one of the frequency signals for providing the artificial engine sound input into the ultra sonic wave vibration modulator 6 is shown in, for example, FIG. 4A. Here, although a voltage change of a single frequency signal is shown in FIG. 4A, a signal waveform of synthesized frequency signals arranged at intervals of 4 Hz is actually provided.

The ultra sonic wave oscillator in the ultra sonic wave vibration modulator 6 oscillates with the ultra sonic wave frequency, which is shown in FIG. 4B.

As shown in FIG. 4C, the ultra sonic wave vibration modulator 6 increases the amplitude of the voltage of the ultra sonic wave oscillation when the signal voltage of the frequency signal for providing the artificial engine sound becomes large. Further, the ultra sonic wave vibration modulator 6 decreases the amplitude of the voltage of the ultra sonic wave oscillation when the signal voltage of the frequency signal for providing the artificial engine sound becomes small. Here, FIG. 4C shows the ultra sonic wave, the amplitude of which is modulated.

Thus, the ultra sonic wave vibration modulator 6 modulates the frequency signal input from the artificial engine sound producing element 5 to the amplitude change of the oscillation voltage of the ultra sonic wave frequency signal.

In the present embodiment, the ultra sonic wave vibration modulator 6 converts the signal voltage change of the frequency signal for providing the artificial engine sound to the amplitude change of the voltage of the ultra sonic wave frequency signal, as shown in FIG. 4C. Alternatively, the signal voltage change of the frequency signal for providing the artificial engine sound may be converted to the width change of generation time of the voltage of the ultra sonic wave frequency signal with using a PWM modulation technique.

The speaker driver 7 drives the Piezo-electric speakers 3 based on the amplitude-modulated ultra sonic wave signal, which is prepared by modulating the amplitude of the frequency signals for providing the artificial engine sound. The amplitude-modulated ultra sonic wave signal is an output signal of the ultra sonic wave vibration modulator 6. Specifically, the speaker driver 7 controls the applied voltage of the Piezo-electric speakers 3, i.e., the speaker driver 7 controls the charging/discharging state of the Piezo-electric speakers 3 so that the Piezo-electric speakers 3 generate the ultra sonic wave, which is prepared by modulating the amplitude of the frequency signals for providing the artificial engine sound. For example, the speaker driver 7 is a power amplifier or a charing and discharging device of the Piezo-electric element. When the waveform signal shown in FIG. 4C is input into the speaker driver 7 from the ultra sonic wave vibration modulator 6, the speaker driver 7 applies the waveform voltage shown in FIG. 4C to the ultra sonic speaker 1 so that the ultra sonic speaker 1, i.e., the Piezo-electric speakers 3, outputs the ultra sonic wave having the output waveform shown in FIG. 4C.

Next, an automatic adjusting element for automatically adjusting the output level (i.e., the sound volume) of the ultra sonic speaker 1 based on the environmental noise around the vehicle will be explained.

The main body device 2 includes the automatic adjusting element for automatically adjusting the amplification gain (i.e., the amplification degree) of the speaker driver 7 based on the environmental noise. The automatic adjusting element includes an environmental noise detector 8 for detecting the environmental noise of the outside of the vehicle, a reader 9 for reading out the sound pressure level of a specific high frequency noise (such as a 4 kHz noise) from the detected environmental noise, and a sound pressure level controller 10 for changing the amplification degree of the speaker driver 7 based on the sound pressure level of the specific high frequency noise in the environmental noise.

The environmental noise detector 8 detects the environmental noise of the outside of the vehicle, which is disposed in a certain range for the artificial engine sound. The environmental noise detector 8 may include a conventional microphone, which is independent from the ultra sonic speaker 1. Alternatively, the environmental noise detector 8 may be one of the Piezo-electric speakers 3 of the ultra sonic speaker 1 so that the one of the Piezo-electric speakers 3 functions as a microphone.

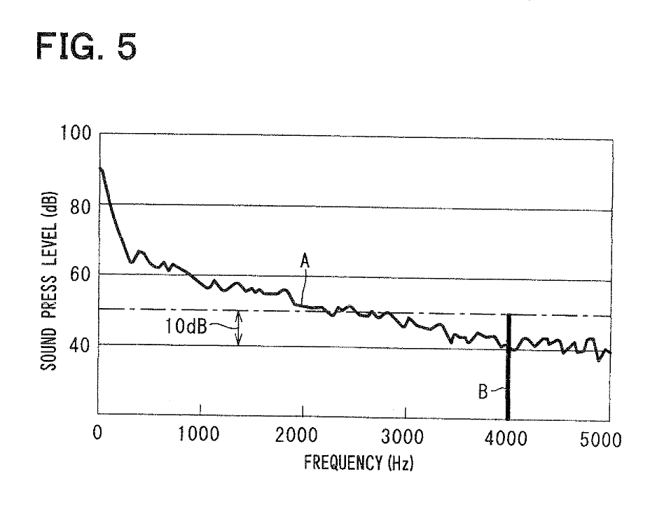

The frequency property of the environmental noise of the outside of the vehicle detected by the environmental noise detector 8 is shown as a solid line A in FIG. 5, for example.

The reader 9 reads out the sound pressure level of the specific high frequency noise such as the 4 kHz noise from the environmental noise detected by the environmental noise detector 8. The reader 9 includes a microphone amplifier for amplifying the detection signal of the environmental noise detector 8.

Specifically, when the frequency property of the environmental noise detected by the environmental noise detector 8 is shown as the solid line A in FIG. 5, the reader 9 reads out the sound pressure level of the environmental noise at 4 kHz. In FIG. 5, the sound pressure level of the environmental noise at 4 kHz is about 40 dB.

The reader 9 for reading out the sound pressure level of the environmental noise at 4 kHz may be provided by the computer, which executes a process for analyzing the sound pressure of the high frequency noise at a specific frequency. Alternatively, the reader 9 may be provided such that the sound pressure level of a certain frequency noise is detected, and the sound pressure level of the specific frequency noise is estimated from the sound pressure level of the detected certain frequency noise.

The sound pressure level controller 10 controls the amplification degree (i.e., the amplification gain) of the speaker driver 7 according to the sound pressure level of the specific frequency noise in the environmental noise. The sound pressure level controller 10 increases the sound pressure level of the specific high frequency signal in the artificial engine sound by a predetermined sound pressure level such as 10 dB from the sound pressure level of the specific high frequency noise in the environmental noise read out by the reader 9. Thus, the sound pressure level of the specific high frequency signal shown as the solid line B in FIG. 4 is obtained. The sound pressure level of the specific high frequency signal in the artificial engine sound is the sound pressure level of the artificial engine sound in the main frequency range L as an object range of the artificial engine sound. For example, the sound pressure level of the artificial engine sound is defined at a place spaced apart from the vehicle by a predetermined distance to the obliquely forward direction on the sidewalk side.

An operation of the vehicle existence notification apparatus will be explained.

The vehicle existence notification apparatus functions when an operation signal is input into the apparatus from the ECU. Specifically, the vehicle existence notification apparatus always functions when the vehicle runs, for example, when the vehicle runs forward. Alternatively, the vehicle existence notification apparatus functions only when the vehicle speed of the vehicle is in a predetermined speed range. Alternatively, the vehicle existence notification apparatus functions only when a pedestrian recognition apparatus (not shown) recognizes existence of a person in a driving direction of the vehicle, and the vehicle runs.

When the vehicle existence notification apparatus functions, the ultra sonic speaker 1 emits the ultra sonic wave, which is not audible and prepared by modulating the amplitude of the signal waveform of the artificial engine sound.

Thus, as shown in FIG. 4D, when the ultra sonic wave moves through the air, the ultra sonic wave having a short wavelength is distorted by air viscosity. FIG. 4D shows the ultra sonic wave, which is being distorted.

Then, as shown in FIG. 4E, the amplitude component in the ultra sonic wave is self-demodulated in the air when the ultra sonic wave moves through the air. FIG. 4E shows the sound after self-demodulation. Thus, the artificial engine sound is produced at the place spaced apart from a source of the ultra sonic wave, which corresponds to the vehicle having the ultra sonic speaker 1.

The vehicle existence notification apparatus generates multiple frequency signals, which are arranged at intervals of 4 Hz so that the artificial engine sound is formed. Thus, memory data for producing the artificial engine sound is simplified, and further, calculation load for producing the artificial engine sound is reduced.

The vehicle existence notification apparatus generates the multiple frequency signals arranged at intervals of 4 Hz for providing the artificial engine sound in a predetermined frequency range such as a range between 250 Hz and 4 kHz, which corresponds to the main frequency range L of the actual engine sound.

Thus, since the frequency range of the artificial engine sound is limited to only the main frequency range L of the actual engine sound, the number of the frequency signals for producing the artificial engine sound is reduced. The calculation load is much reduced.

The vehicle existence notification apparatus processes the frequency property of multiple frequency signals arranged at intervals of 4 Hz to be similar to the frequency property of the actual engine sound of the specific type of the vehicle.

Thus, the artificial engine sound generated by the vehicle existence notification apparatus resembles the actual engine sound of the specific type of the vehicle.

In the vehicle existence notification apparatus, the artificial engine sound includes the high frequency sound such as 4 kHz sound, which is dissonance and abrasive for a person so that the sounds easily stick in his or her ear. Thus, a person easily recognizes the artificial engine sound. The high frequency sound in the artificial engine sound provides to notify the existence of the vehicle to a person around the vehicle with high provability.

Since the artificial engine sound further includes the low frequency sound and the middle frequency sound such as a 2 kHz sound, a 1 kHz sound, a 500 Hz sound and a 250 Hz sound, which are overtone of a 4 kHz sound. The low and middle frequency sounds are harmonious for a person, and, for example, constitute multiple frequency signals having overtone relationship. Thus, the artificial engine sound is made harmonious, and therefore, a sense of discomfort for a person with respect to the artificial engine sound is reduced.

The artificial engine sound generated by the vehicle existence notification apparatus provides to reduce the sense of discomfort for a person and to notify the existence of the vehicle with high provability.

The vehicle existence notification apparatus emits the artificial engine sound to the outside of the vehicle through the parametric speaker.

Since the parametric speaker is used, the artificial engine sound is produced at the place spaced apart from the vehicle, Further, since the parametric speaker has strong directivity, the parametric speaker can produces the artificial engine sound to a specific direction only.

Thus, the parametric speaker produces the artificial engine sound at the place spaced apart from the vehicle by a predetermined distance to the slant forward direction of the vehicle on the sidewalk side. The place is disposed in a predetermined range, at which the existence of the vehicle is required to be notified. Specifically, the apparatus does not produce the artificial engine sound at a place disposed in a range, at which the existence of the vehicle is not required to be notified. Thus, the apparatus reduces unnecessary artificial engine sound as an artificial engine noise.

The vehicle existence notification apparatus automatically adjusts the sound pressure level of the artificial engine sound based on the environmental noise of the outside of the vehicle.

Thus, the sound pressure level of the artificial engine sound is larger than the sound pressure level of the environmental noise. Further, the sound pressure level of the artificial engine sound is appropriately controlled so that the sound pressure level does not become unnecessarily large. Thus, the apparatus notifies the existence of the vehicle with high provability with using the artificial engine sound. Further, the artificial noise is reduced.

### Second Embodiment

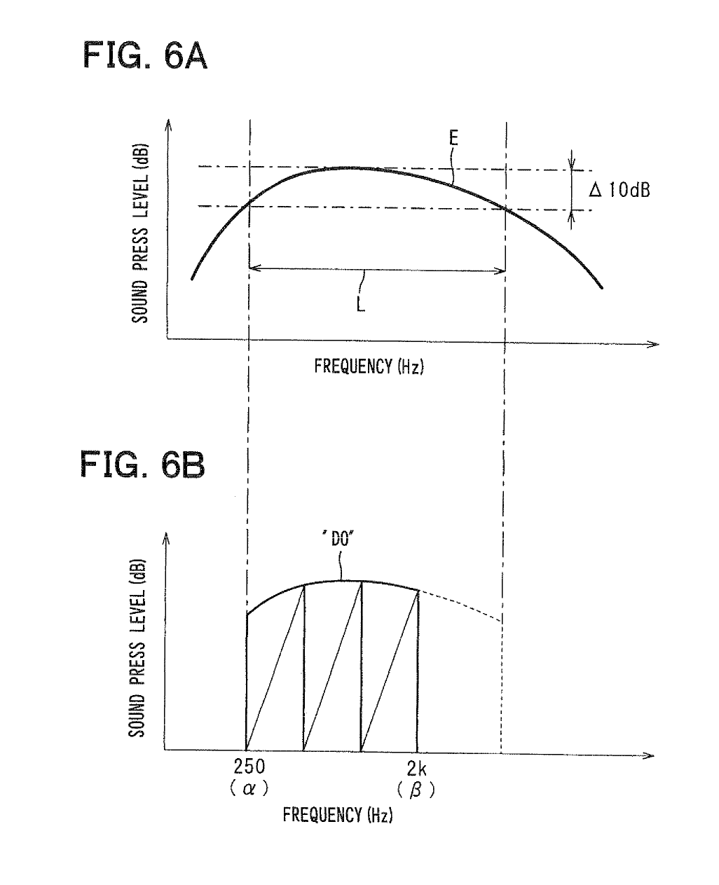

A second embodiment will be explained with reference to FIG. 6. In the present embodiment, the apparatus produces one of music scales selected from equitempered scales as the artificial engine sound so that music scale artificial engine sound is produced. The equitempered scales includes a sound of “Do,” a sound of “Do sharp,” a sound of “Re,” a sound of “Re sharp,” a sound of “Mi,” a sound of “Fa,” a sound of “Fa sharp,” a sound of “Sol,” a sound of “Sol sharp,” a sound of “La,” a sound of “La sharp,” ad a sound of “Si.”

Specifically, the artificial engine sound producing program executed by the artificial engine sound producing element 5 includes a music scale producing program for producing the frequency signal of the artificial engine sound, which strikes the equitempered scale in such a manner that the frequency range of multiple frequency signals arranged at intervals of 4 Hz is limited to a certain range.

The music scale producing program will be explained as follows.

First, one of the equitempered scales of a group of a sound of “Do,” a sound of “Do sharp,” a sound of “Re,” a sound of “Re sharp,” a sound of “Mi,” a sound of “Fa,” a sound of “Fa sharp,” a sound of “Sol,” a sound of “Sol sharp,” a sound of “La,” a sound of “La sharp,” and a sound of “Si” is selected. The selected one equitempered scale has a basic music scale frequency α.

In the present embodiment, the basic music scale frequency α is 250 Hz, which provides the sound of “Do.”

Next, a high dimension music scale frequency β is calculated based on the basic music scale frequency α. The high dimension music scale frequency β has a music scale higher by one or more octaves than that of the basic music scale frequency α.

Specifically, in the present embodiment, the high dimension music scale frequency β is 2 kHz, which provides the music scale of “Do” higher by three octaves than the music scale of “Do” in the basic music scale frequency α.

The music scale producing program executed by the artificial engine sound producing element 5 produces the frequency signal of the music scale artificial engine sound of the sound of “Do” such than the range of the frequency signals arranged at intervals of 4 Hz is limited to a range between 250 Hz (the sound of “Do”) and 2 kHz (the sound of “Do” higher by three octaves than the basic sound of “Do”).

The frequency signals for providing the music scale artificial engine sound of the sound of “Do” produced by the artificial engine sound producing element 5 is modulated to the ultra sonic wave by the ultra sonic wave vibration modulator 6, and then, the modulated ultra sonic wave is output from the ultra sonic speaker 1 to the outside of the vehicle. While the ultra sonic wave propagates through the air, the amplitude component in the ultra sonic wave is self-demodulated. Thus, the music scale artificial engine sound of the sound of “Do” is produced at a place spaced apart from the vehicle.

Thus, the artificial engine sound having a predetermined music scale is generated.

In this case, the frequency property processing program may be used for processing the frequency property so that the artificial engine sound having a predetermined music scale resembles the actual engine sound of the specific type of the vehicle.

### Third Embodiment

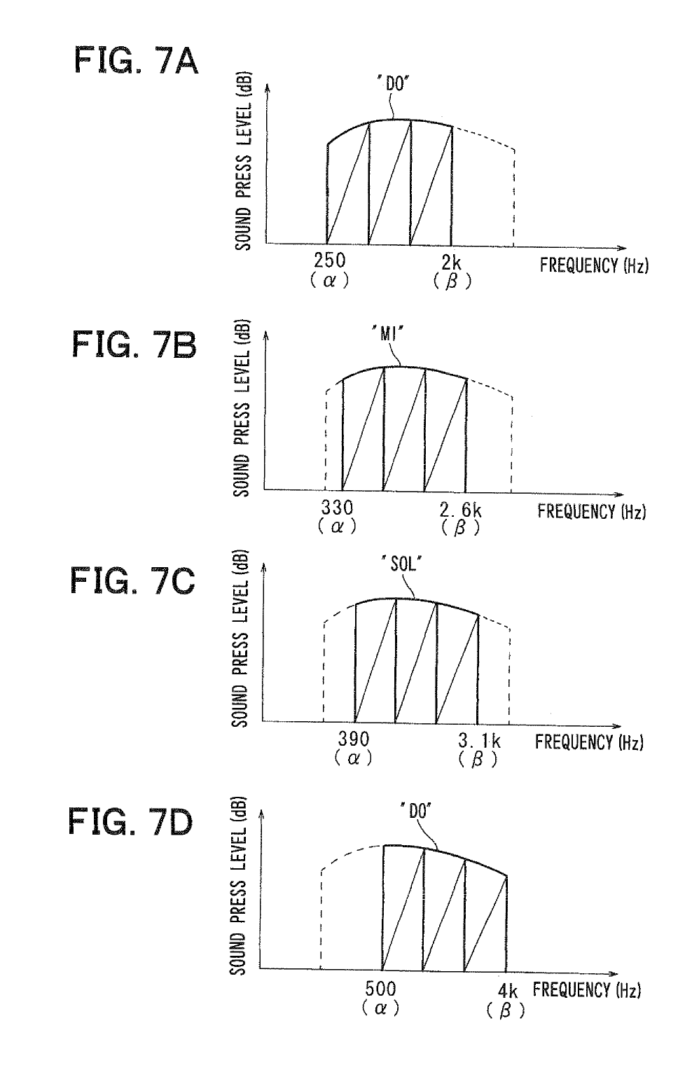

A third embodiment will be explained with reference to FIGS. 7A to 7D.

In the second embodiment, the artificial engine sound has one music scale.

In the present embodiment, multiple artificial engine sounds having different music scales are overlapped so that the artificial engine sound has a chord sound.

Specifically, the artificial engine sound producing program executed by the artificial engine sound producing element 5 includes a chord sound producing program for producing the frequency signals, which provide the artificial engine sound striking the chord sound in such a manner that multiple frequency signals of the artificial engine sounds of the music scales are overlapped.

The chord sound producing program will be explained as follows.

First, multiple music scales for providing the chord sound are selected. The chord sounds may be a major key chord sound or a minor key chord sound such as equitempered scales of “Do,” “Mi” and “Sol,” equitempered scales of “Re,” “Fa” and “La,” equitempered scales of “Mi,” “Sol” and “Si,” equitempered scales of “La,” “Do” and “Mi,” equitempered scales of “Si,” “Re” and “Fa,” and the like.

In the present embodiment, the chord sound includes the sound of “Do” on a low pitch sound side, the sound of “Mi,” the sound of “Sol” and the sound of “Do” on a high pitch sound side.

First, the frequency signals having the artificial engine sound of “Do” on the low pitch sound side are produced.

In this case, the basic music scale frequency a is selected to be 250 Hz, which provides the sound of “Do” on the low pitch sound side. Then, the high dimension music scale frequency β is selected to be 2 kHz, which provides the sound of “Do” higher by three octaves than the sound of “Do” on the low pitch sound side.

Thus, as shown in FIG. 7A, multiple frequency signals arranged at the intervals of 4 Hz for providing the artificial engine sound is generated in a range between 250 Hz and 2 kHz, so that the frequency signals providing the artificial engine sound providing the sound of “Do” on the low pitch sound side is generated.

Similarly, the frequency signals providing the sound of “Mi” are generated. First, the basic music scale frequency a is selected to be 330 Hz, which provides the sound of “Mi.” Then, the high dimension music scale frequency β is selected to be 2.6 kHz, which provides the sound of “Mi” higher by three octaves than the sound of “Mi.”

Thus, as shown in FIG. 7B, multiple frequency signals arranged at the intervals of 4 Hz for providing the artificial engine sound is generated in a range between 330 Hz and 2.6 kHz, so that the frequency signals providing the artificial engine sound providing the sound of “Mi” is generated.

Similarly, the frequency signals providing the sound of “Sol” are generated. First, the basic music scale frequency a is selected to be 390 Hz, which provides the sound of “Sol.” Then, the high dimension music scale frequency β is selected to be 3.1 kHz, which provides the sound of “Sol” higher by three octaves than the sound of “Sol.”

Thus, as shown in FIG. 7C, multiple frequency signals arranged at the intervals of 4 Hz for providing the artificial engine sound is generated in a range between 390 Hz and 3.1 kHz, so that the frequency signals providing the artificial engine sound providing the sound of “Sol” is generated.

Similarly, the frequency signals providing the sound of “Do” on the high pitch sound side are generated. First, the basic music scale frequency a is selected to be 500 Hz, which provides the sound of “Do” on the high pitch sound side. Then, the high dimension music scale frequency β is selected to be 4 kHz, which provides the sound of “Do” higher by three octaves than the sound of “Do” on the high pitch sound side.

Thus, as shown in FIG. 7D, multiple frequency signals arranged at the intervals of 4 Hz for providing the artificial engine sound is generated in a range between 500 Hz and 4 kHz, so that the frequency signals providing the artificial engine sound providing the sound of “Do” on the high pitch sound side is generated.

Thus, the chord sound producing program provides to overlap the frequency signals of the artificial engine sound providing the sound of “Do” on the low pitch sound side shown in FIG. 7A, the frequency signals of the artificial engine sound providing the sound of “Mi” shown in FIG. 7B, the frequency signals of the artificial engine sound providing the sound of “Sol” shown in FIG. 7C, and the frequency signals of the artificial engine sound providing the sound of “Do” on the high pitch sound side shown in FIG. 7D. Thus, the frequency signals of the artificial engine sound providing the chord sound of equitempered scales of “Do,” “Mi,” “Sol” and “Do” are generated.

The frequency signals of the artificial engine sound providing the chord sound of equitempered scales of “Do,” “Mi,” “Sol” and “Do” generated in the chord sound producing program executed by the artificial engine sound producing element 5 are modulated to the ultra sonic wave by the ultra sonic wave vibration modulator 6, and then, the modulated ultra sonic wave is output from the ultra sonic speaker 1 to the outside of the vehicle.

While the ultra sonic wave propagates through the air, the amplitude component in the ultra sonic wave is self-demodulated. Thus, the music scale artificial engine sound of the chord sound of “Do,” “Mi,” “Sol” and “Do” is produced at a place spaced apart from the vehicle. The music scale artificial engine sound of the chord sound of “Do,” “Mi,” “Sol” and “Do” is in a range between 250 Hz and 4 kHz.

Thus, the chord sound, which is comfortable for a person, in the artificial engine sound is produced, so that the artificial engine sound is favorable for a person. The favorability of the artificial engine sound is improved.

Since the artificial engine sound includes the high frequency sound, i.e., the high pitch sound such as a 4 kHz sound, which is dissonance and abrasive for a person so that the sounds easily stick in his or her ear, a person easily recognizes the artificial engine sound. Thus, the high pitch sound in the artificial engine sound provides to notify the existence of the vehicle to a person around the vehicle. Further, the artificial engine sound includes the low pitch frequency sound (i.e., the low frequency sound) and the middle pitch frequency sound (i.e., the middle frequency sound), which provide harmonious for a person. For example, the low pitch frequency sound and the middle pitch frequency sound are a 2 kHz sound, a 1 kHz sound, a 500 Hz sound and a 250 Hz sound, which are overtones of a 4 kHz sound. Thus, a person feels the artificial engine sound to be harmonious.

Thus, in the present embodiment, the chord sound is generated by the artificial engine sound for providing to reduce a sense of discomfort and to secure the notification of the existence of the vehicle with high provability.

In the above embodiments, the apparatus produces the artificial engine sound to the forward direction of the vehicle when the vehicle runs forward. Alternatively, the apparatus may produce the artificial engine sound to the backward direction and around the rear side of the vehicle when the vehicle is reversed.

In the above embodiments, with using the parametric speaker, the artificial engine sound is produced at a place spaced apart from the vehicle. Alternatively, an artificial engine sound generator such as an ordinary speaker mounted on the vehicle may directly output the artificial engine sound, which is audible. Alternatively, the parametric speaker and the artificial engine sound generator such as an ordinary speaker may be switched according to a traffic condition.

In the above embodiments, the selected frequency AHz is set to be 4 Hz. Alternatively, the selected frequency AHz may be changeable according to the opening degree of acceleration pedal and/or the vehicle speed. Alternatively, the selected frequency AHz may be fluctuated temporally, similar to the temporally fluctuation of the frequency component of the actual engine sound.

In the above embodiments, the sound pressure level of the artificial engine sound is automatically adjusted according to the environmental noise. Alternatively, the sound pressure level of the artificial engine sound may be adjusted according to the opening degree of acceleration pedal and/or the vehicle speed. Alternatively, the sound pressure level of the artificial engine sound may be fluctuated temporally, similar to the temporally fluctuation of the sound pressure component of the actual engine sound.

Here, when the selected frequency AHz and/or the sound pressure level of the artificial engine sound are fluctuated, the fluctuation may be provided by a unequally-pitch fluctuation such as a 1/f fluctuation.

In the above embodiments, the vehicle existence notification apparatus includes the artificial engine sound generator. Alternatively, the artificial engine sound may be output to a compartment of the vehicle. For example, when a driver is unfamiliar with an electric motor driving vehicle (i.e., a driver is familiar with a combustion engine vehicle), a driving support apparatus may include the artificial engine sound generator for generating the artificial engine sound as a feed back sound of an operation of the vehicle. Alternatively, the artificial engine sound generator may be mounted on a racing game machine or a driving simulator.

The above disclosure has the following aspects.

According to an aspect of the present disclosure, an artificial engine sound generator for producing an artificial engine sound includes: a main body device that defines a predetermined frequency selected in a range between 1 Hz and 10 Hz, and simultaneously generates a plurality of signals having frequencies, which are arranged at intervals of the predetermined frequency, so that the artificial engine sound is formed.

In the above generator, it is not necessary to divide a waveform data of an actual combustion engine sound into a waveform data in one combustion cycle as a data unit. Further, it is not necessary to store multiple unit waveform data in accordance with an opening degree of an acceleration pedal. Thus, data for producing the artificial engine sound is minimized.

Further, it is not necessary to read out one unit waveform data from multiple unit waveform data. Further, it is not necessary to couple the one unit waveform data, and to overlap the one unit waveform data. Accordingly, a calculation load for producing the artificial engine sound is reduced.

Thus, since the main body device simultaneously generates a plurality of signals having frequencies, which are arranged at intervals of the predetermined frequency, data for producing the artificial engine sound is minimized, and a calculation load for producing the artificial engine sound is reduced.

Alternatively, the predetermined frequency may be constant or variable in the range between 1 Hz and 10 Hz. Further, the predetermined frequency may be constant and fixed to be 4 Hz.

Alternatively, the main body device may include an artificial engine sound producing element, and the artificial engine sound producing element simultaneously generates the plurality of signals having the frequencies in a predetermined frequency range. Since the plurality of signals are generated only in the predetermined frequency range, the number of the signals for producing the artificial engine sound is reduced. Thus, the calculation load for producing the artificial engine sound is reduced.

Alternatively, the main body device may include an artificial engine sound producing element, and the artificial engine sound producing element processes a frequency property of the plurality of signals, Thus, the generator can resemble the artificial engine sound to an actual engine sound of a specific vehicle.

Alternatively, the main body device may include an artificial engine sound producing element. The artificial engine sound producing element defines one music scale selected from equitempered scales. The one music scale has a basic music scale frequency. The artificial engine sound producing element simultaneously generates the plurality of signals having the frequencies in a range between the basic music scale frequency and a high dimension music scale frequency so that the artificial engine sound providing the one music scale is prepared. The high dimension music scale frequency is higher by one or more octaves than the basic music scale frequency. Further, the equitempered scales may include a sound of “Do,” a sound of “Do sharp,” a sound of “Re,” a sound of “Re sharp,” a sound of “Mi,” a sound of “Fa,” a sound of “Fa sharp,” a sound of “Sol,” a sound of “Sol sharp,” a sound of “La,” a sound of “La sharp,” and a sound of “Si.” The high dimension music scale frequency is higher by three octaves than the basic music scale frequency.

Alternatively, the artificial engine sound producing element may produce a plurality of artificial engine sound components providing different music scales, respectively. The artificial engine sound producing element overlaps the plurality of artificial engine sound components providing different music scales so that the artificial engine sound providing a chord sound is prepared. Further, the chord sound may be equitempered scales of “Do,” “Mi” and “Sol,” equitempered scales of “Re,” “Fa” and “La,” equitempered scales of “Mi,” “Sol” and “Si,” equitempered scales of “La,” “Do” and “Mi,” or equitempered scales of

“Si,” “Re” and “Fa.”

Alternatively, the main body device may include a parametric speaker for outputting the artificial engine sound to an outside of a vehicle. Since the parametric speaker has strong directivity, the parametric speaker can produces the artificial engine sound to a specific direction only. Further, the parametric speaker produces the artificial engine sound at the place spaced apart from the vehicle by a predetermined distance. Specifically, the generator does not produce the artificial engine sound at a place disposed in a range, at which the existence of the vehicle is not required to be notified. Thus, the generator reduces unnecessary artificial engine sound as an artificial engine noise.

Here, if the generator includes a small sized speaker such as a micro speaker for generating audible sound so that the speaker directly generate the audible artificial engine sound, the small sized speaker hardly produces a middle and low pitch sound. Thus, the sound pressure level of the artificial engine sound at the middle and low pitch sound generated by the small sized speaker is reduced. Thus, reproducibility of the artificial engine sound is reduced. The artificial engine sound does not provide the frequency property of the actual combustion engine sound. However, since the parametric speaker emits the ultra sonic wave, the dimensions of the ultra sonic speaker are minimized. Further, the amplitude component in the ultra sonic wave is demodulated through the air, and therefore, the middle and low pitch sound is easily reproduced. As a result, when the parametric speaker is used, the artificial engine sound has the frequency property, which is similar to that of the actual combustion engine sound.

Further, the actual engine sound includes multiple degree components, which constitute overtones, Specifically, the actual engine sound constitutes the overtones in a frequency range equal to or lower than 4 kHz. Thus, when the overtones are reproduced, the artificial engine sound resembles the actual engine sound. The parametric speaker easily generates the overtones. Accordingly, the parametric speaker easily produces the artificial engine sound including overtones. Thus, the artificial engine sound output from the parametric speaker resembles the actual engine sound.

Alternatively, the vehicle may be an electric vehicle, a fuel cell vehicle or a hybrid vehicle.

Alternatively, the artificial engine sound generator may further include: an ultrasonic speaker for generating an ultra sonic wave. The main body device includes: an artificial engine sound producing element for simultaneously generating the plurality of signals; an ultra sonic wave amplitude modulator for modulating the plurality of signals to ultra sonic wave signals having ultra sonic frequencies; and a speaker driver for driving the ultrasonic speaker according to the ultra sonic wave signals. The ultrasonic speaker, the artificial engine sound producing element, the ultra sonic wave amplitude modulator and the speaker driver provide the parametric speaker. Further, the artificial engine sound generator may further include: a environmental noise detector for detecting an environmental noise around the vehicle. The main body device further includes a reader and a sound pressure level controller. The reader reads out a sound pressure level of a specific high frequency noise from the detected environmental noise. The sound pressure level controller changes an amplification degree of the speaker driver based on the sound pressure level of the specific high frequency noise in the environmental noise.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. An artificial engine sound generator for producing an artificial engine sound comprising:
a main body device that defines a predetermined frequency selected in a range between 1 Hz and 10 Hz, and simultaneously generates a plurality of signals having frequencies, which are arranged at intervals of the predetermined frequency, so that the artificial engine sound is formed.

2. The artificial engine sound generator according to claim 1,
wherein the predetermined frequency is constant or variable in the range between 1 Hz and 10 Hz.

3. The artificial engine sound generator according to claim 2,
wherein the predetermined frequency is constant and fixed to be 4 Hz.

4. The artificial engine sound generator according to claim 1,
wherein the main body device includes an artificial engine sound producing element, and
wherein the artificial engine sound producing element simultaneously generates the plurality of signals having the frequencies in a predetermined frequency range.

5. The artificial engine sound generator according to claim 1,
wherein the main body device includes an artificial engine sound producing element, and
wherein the artificial engine sound producing element processes a frequency property of the plurality of signals.

6. The artificial engine sound generator according to claim 1,
wherein the main body device includes an artificial engine sound producing element,
wherein the artificial engine sound producing element defines one music scale selected from equitempered scales,
wherein the one music scale has a basic music scale frequency, wherein the artificial engine sound producing element simultaneously generates the plurality of signals having the frequencies in a range between the basic music scale frequency and a high dimension music scale frequency so that the artificial engine sound providing the one music scale is prepared, and
wherein the high dimension music scale frequency is higher by one or more octaves than the basic music scale frequency.

7. The artificial engine sound generator according to claim 6,
wherein the equitempered scales include a sound of “Do,” a sound of “Do sharp,” a sound of “Re,” a sound of “Re sharp,” a sound of “Mi,” a sound of “Fa,” a sound of “Fa sharp,” a sound of “Sol,” a sound of “Sol sharp,” a sound of “La,” a sound of “La sharp,” and a sound of “Si,” and
wherein the high dimension music scale frequency is higher by three octaves than the basic music scale frequency.

8. The artificial engine sound generator according to claim 6,
wherein the artificial engine sound producing element produces a plurality of artificial engine sound components providing different music scales, respectively,
wherein the artificial engine sound producing element overlaps the plurality of artificial engine sound components providing different music scales so that the artificial engine sound providing a chord sound is prepared.

9. The artificial engine sound generator according to claim 8,
wherein the chord sound is equitempered scales of “Do,” “Mi” and “Sol,” equitempered scales of “Re,” “Fa” and “La,” equitempered scales of “Mi,” “Sol” and “Si,” equitempered scales of “La,” “Do” and “Mi,” or equitempered scales of “Si,” “Re” and “Fa.”

10. The artificial engine sound generator according to claim 1,
wherein the main body device includes a parametric speaker for outputting the artificial engine sound to an outside of a vehicle.

11. The artificial engine sound generator according to claim 10,
wherein the vehicle is an electric vehicle, a fuel cell vehicle or a hybrid vehicle.

12. The artificial engine sound generator according to claim 10, further comprising:
an ultrasonic speaker for generating an ultra sonic wave,
wherein the main body device includes:
an artificial engine sound producing element for simultaneously generating the plurality of signals;
an ultra sonic wave amplitude modulator for modulating the plurality of signals to ultra sonic wave signals having ultra sonic frequencies; and
a speaker driver for driving the ultrasonic speaker according to the ultra sonic wave signals, and
wherein the ultrasonic speaker, the artificial engine sound producing element, the ultra sonic wave amplitude modulator and the speaker driver provide the parametric speaker.

13. The artificial engine sound generator according to claim 12, further comprising:
a environmental noise detector for detecting an environmental noise around the vehicle,
wherein the main body device further includes a reader and a sound pressure level controller,
wherein the reader reads out a sound pressure level of a specific high frequency noise from the detected environmental noise, and
wherein the sound pressure level controller changes an amplification degree of the speaker driver based on the sound pressure level of the specific high frequency noise in the environmental noise.
